(19) United States
(12) Patent Application Publication
(10) Pub. No.: US 2016/0148789 A1
(43) Pub. Date: May 26, 2016

(54) PRE-CLEANING CHAMBER AND A SEMICONDUCTOR PROCESSING APPARATUS CONTAINING THE SAME

(71) Applicant: BEIJING NMC CO., LTD, Beijing (CN)

(72) Inventors: PENG CHEN, Beijing (CN); YOU LV, Beijing (CN); PEIJUN DING, Beijing (CN); JINGSHAN YANG, Beijing (CN); GUODONG BIAN, Beijing (CN); MENGXIN ZHAO, Beijing (CN); QING SHE, Beijing (CN); WEI LI, Beijing (CN)

(73) Assignee: BEIJING NMC CO., LTD

(21) Appl. No.: 15/012,941

(22) Filed: Feb. 2, 2016

Related U.S. Application Data
(63) Continuation of application No. PCT/CN2014/083709, filed on Aug. 5, 2014.

(30) Foreign Application Priority Data
Aug. 7, 2013 (CN) 2013-10341787.3

(51) Int. Cl. H01J 37/32

(52) U.S. Cl. CPC H01J 37/32871; H01J 37/32422; H01J 37/32495; H01J 37/32651; H01J 2237/335

(57) ABSTRACT

The present disclosure provides a pre-cleaning chamber. The pre-cleaning chamber includes a cavity, a top cover of the cavity, and an ion filtering unit with venting holes. The ion filtering unit is configured to divide the cavity into an upper sub-cavity and a lower sub-cavity and to filter out ions from plasma when the plasma is moving through the filtering unit from the upper sub-cavity to the lower sub-cavity. The pre-cleaning chamber further includes a carry unit located in the lower sub-cavity for supporting a wafer.

### CROSS-REFERENCES TO RELATED APPLICATIONS

This application claims the priority of PCT/CN2014/083709 filed on Aug. 5, 2014, which claims priority of Chinese Patent Application No. 201310341787.3 filed on Aug. 7, 2013, the entire content of all of which is incorporated herein by reference.

### FIELD OF THE DISCLOSURE

The present disclosure relates to the field of semiconductor manufacturing device and, more particularly, relates to a pre-cleaning chamber and a semiconductor processing apparatus containing the same.

### BACKGROUND

Semiconductor processing apparatus is currently widely used in the manufacturing processes of semiconductor integrated circuits, solar cells, flat display panels and other products. The semiconductor processing apparatus, widely used in industry field, utilizes different types of plasma for processing, such as the DC discharge plasma, capacitively coupled plasma (CCP), inductively coupled plasma (ICP), and electron cyclotron resonance (ECR) plasma. The semiconductor processing apparatus are often used in manufacturing processes including steps such as deposition, etching, and cleaning.

During the manufacturing processes, in order to improve product quality, a pre-clean process is often performed to remove oxides and other impurities on the wafers before a deposition process. Conventionally, the working principle of a pre-cleaning chamber often includes forming plasma by exciting a cleaning gas, such as argon, helium, or hydrogen in the chamber. The formed plasma is used to perform chemical reaction and physical bombardment on the wafer. Thus, the impurities on the surface of the wafer can be removed.

FIG. 1 shows a schematic structural view of an existing pre-cleaning chamber. As shown in FIG. 1, the pre-cleaning chamber includes a side wall 1, a bottom wall 2, and a top cover 9. A base pedestal 4 used for holding wafers is located at the bottom of the pre-cleaning chamber. The base pedestal 4 is connected with a first matching device 7 and a first radio frequency (RF) power supply 8, sequentially. The top cover 9 has a dome shape, and is made of insulating materials, such as ceramic and/or quartz. Coil 3 is wound and overlying above the top cover 9. More specifically, coil 3 is a helical solenoid, which is wound to form a circular cylinder. The diameter or outer diameter of the circular cylinder may correspond to the diameter or outer diameter of the side wall 1. The coil 3 is connected to a second matching device 5 and a second RF power supply 6, sequentially. In a pre-clean process, the second RF power supply 6 is powered on to excite the gas in the chamber into plasma. Meanwhile, the first RF power supply is powered on to attract the ions in the plasma to bombard the impurities on the wafer.

In the semiconductor manufacturing process, as the integration levels of chips increase, the widths of the interconnections and wire spacing have been reduced. As a result, resistance and parasitic capacitance increase, which further increases delays of RC signals. Thus, low-k materials, i.e., materials with low dielectric constants, are used as interlayer dielectrics. However, in the pre-clean process, technical issues may still arise. For example, ions in the plasma may generate certain kinetic energy under the sheath voltage of the plasma. The ions may penetrate into the low-k material when the kinetic energy drive the ions to move close to the wafer surface. As a result, the quality of the low-k material may degrade, which may further adversely affect product performance.

### BRIEF SUMMARY OF THE DISCLOSURE

The present disclosure provides a pre-cleaning chamber and a semiconductor processing apparatus to overcome at least one of the technical problems in the related technologies. The apparatus provided in this disclosure is able to prevent low-k material from being adversely affected by ions in plasma, by filtering the ions from the plasma when the plasma is moving towards the wafer surface. Embodiments of the present disclosure may improve the performance of related products.

One aspect of the present disclosure provides a pre-cleaning chamber. The pre-cleaning chamber includes a cavity, a top cover of the cavity, an ion filtering unit with venting holes. The ion filtering unit is configured to divide the cavity into an upper sub-cavity and a lower sub-cavity and to filter out ions from plasma when the plasma is moving through the filtering unit from the upper sub-cavity to the lower sub-cavity. The pre-cleaning chamber also includes a carrying unit located in the lower sub-cavity for supporting a wafer.

Optionally, the ion filtering unit includes one or more filtering plates; and each filtering plate includes a plurality of venting holes distributed in the filtering plate. At least one of the filtering plates includes venting holes with maximum diameters no greater than a sheath thickness of plasma times two.

Optionally, the ion filtering unit includes one filtering plate. The one filtering plate divides the cavity into the upper sub-cavity and the lower sub-cavity. The plurality of venting holes connect the upper sub-cavity and the lower sub-cavity.

Optionally, the ion filtering unit includes N filtering plates arranged vertically in the cavity, N being an integer greater than 1. The filtering plates divide the cavity into the lower sub-cavity, (N−1) middle sub-cavities, and the upper sub-cavity.

Optionally, the venting holes are distributed uniformly in the filtering plate.

Optionally, the venting holes are distributed in the filtering plate according to processing deviations on a wafer placed on the carrying unit.

Optionally, a distribution density of the venting holes is determined according to a processing rate.

Optionally, a venting hole is a through hole with a trapezoid shaped cross section or a step-shaped cross section.

Optionally, the venting holes are through holes, a diameter of a venting hole ranging from about 0.2 mm to about 20 mm.

Optionally, the venting holes are cone-shaped holes or multi-cylinder-shaped holes, a maximum diameter of a venting hole being no greater than 20 mm, and a minimum diameter of a venting hole being no smaller than 0.2 mm.

Optionally, the filtering plate is made of an insulating material, a metal coated with insulating materials, or a combination thereof.

Optionally, a thickness of a filtering plate ranges from about 2 mm to about 50 mm.

Optionally, the carrying unit includes a heating device for heating the wafer.

Optionally, the carrying unit includes an electrostatic chuck for fixing the wafer by electrostatic forces, and the heating device is positioned in the electrostatic chuck.

Optionally, the cavity includes a protection layer on an inner surface of the cavity, the protection layer being of an insulating material.

Optionally, the cavity further includes an inner liner on an inner sidewall of the cavity, the inner liner being made of an insulating material, a metal coated with insulating material, or a combination thereof.

Optionally, the top cover is of a dome shape, and is made of an insulating material.

Optionally, the top cover is of a barrel shape, with a top ceiling, and made of an insulating material.

Optionally, the top cover further includes a Faraday shielding piece that is positioned on an inner sidewall of the top cover, the Faraday shielding piece being made of a metal, an insulating material coated with a conductive material, or a combination thereof.

Optionally, the Faraday shielding piece includes at least one slit along an axial direction of and extending through the shielding piece.

Optionally, the pre-cleaning chamber includes an inductance coil, and an RF matching device and a radio frequency (RF) power supply connected to the inductance coil sequentially. The inductance coil is wound and overlying along an outer periphery of a sidewall of the top cover, the inductance coil being a helical solenoid with one or more turns. The RF power supply provides RF power to the inductance coil.

Optionally, diameters of turns of the helical solenoid are same or increase from top to bottom of the helical solenoid.

Another aspect of the present disclosure provides a plasma processing apparatus. The apparatus includes one or more of the pre-cleaning chambers as described above.

Another aspect of the present disclosure provides a wafer pre-cleaning process. The process includes providing a pre-cleaning chamber with a cavity, a top cover of the cavity, an ion filtering unit dividing the cavity into an upper sub-cavity and a lower sub-cavity, the ion filtering unit including venting holes, and a carrying unit located in the lower sub-cavity. The process further includes placing a wafer on the carrying unit; forming plasma in the upper sub-cavity; filtering out ions from the plasma when the plasma moves through the filtering unit from the upper sub-cavity into the lower sub-cavity through the venting holes; and pre-cleaning the wafer on the carrying unit.

Optionally, the ion filtering unit includes one or more filtering plates, each filtering plate having a plurality of venting holes.

Optionally, the top cover is of a dome shape or of a barrel shape.

The present disclosure has several advantages. In the pre-cleaning chamber provided by the present disclosure, by arranging the ion filtering unit above the carrying unit in the cavity, ions in the plasma may be filtered out when the plasma is moving downward to the carrying unit during the pre-cleaning process. Only free radicals, atoms, and molecules are able to reach the wafer surface on the carrying unit. Adverse effects on the low-k materials on the wafer, caused by ions in the plasma, may be prevented. The pre-cleaning chamber may have improved performance. Further, because the plasma passing through the ion filtering unit does not contain ions, the free radicals, atoms, and molecules may diffuse onto the wafer surface. No biasing voltage is needed to be applied on the wafer. Biasing devices such as biasing power supply and matching devices are not needed. The fabrication cost of the pre-cleaning chamber may be further reduced.

In the semiconductor processing apparatus provided by the present disclosure, by using the disclosed pre-cleaning chamber, adverse effects on the low-k materials on the wafer caused by ions in the plasma, may be reduced or prevented. The plasma processing apparatus may have improved performance.

### BRIEF DESCRIPTION OF THE DRAWINGS

The following drawings are merely examples for illustrative purposes according to various disclosed embodiments and are not intended to limit the scope of the present disclosure.

FIG. 1 illustrates a schematic diagram of an existing pre-cleaning chamber;

FIG. 2A illustrates a schematic diagram of an exemplary pre-cleaning chamber according to the first embodiment of the present disclosure;

FIG. 2B illustrates a top view of an exemplary filtering plate shown in FIG. 2A;

FIG. 2C illustrates a cross-sectional view of an exemplary venting hole along an axial direction as shown in FIG. 2A;

FIG. 3 illustrates a schematic diagram of another exemplary pre-cleaning chamber according to the first embodiment of the present disclosure;

FIG. 4 illustrates a schematic diagram of an exemplary pre-cleaning chamber according to the second embodiment of the present disclosure; and

FIG. 5 illustrates the cross-sectional view of an exemplary Faraday shield along a radial direction as shown in FIG. 4.

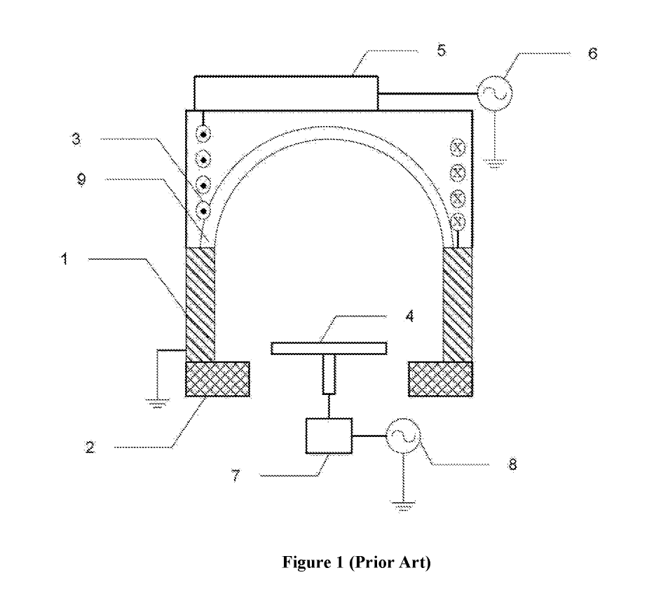

### DETAILED DESCRIPTION

For those skilled in the art to better understand the technical solution of the invention, reference will now be made in detail to exemplary embodiments of the invention, which are illustrated in the accompanying drawings. Wherever possible, the same reference numbers will be used throughout the drawings to refer to the same or like parts.

It should be noted that in this disclosure, the figures are only for illustrative purposes and do not reflect the actual ratios or dimensions of the objects.

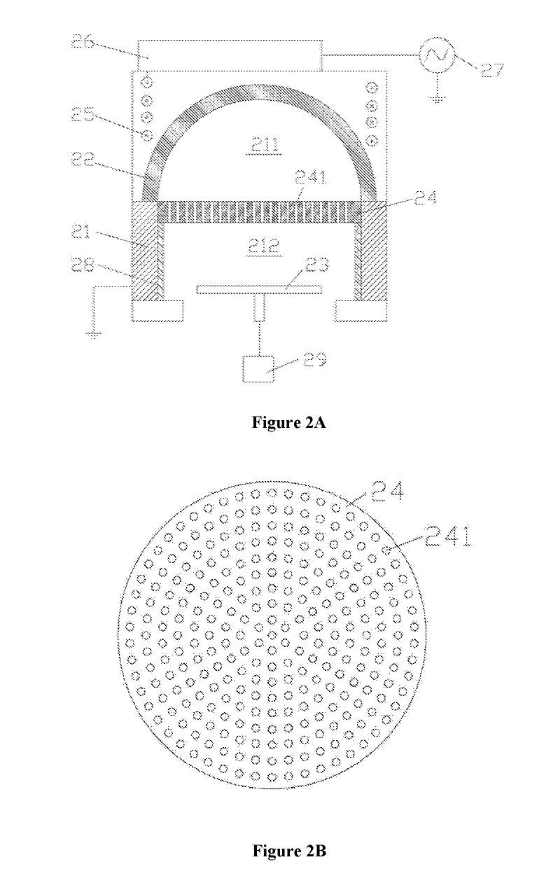

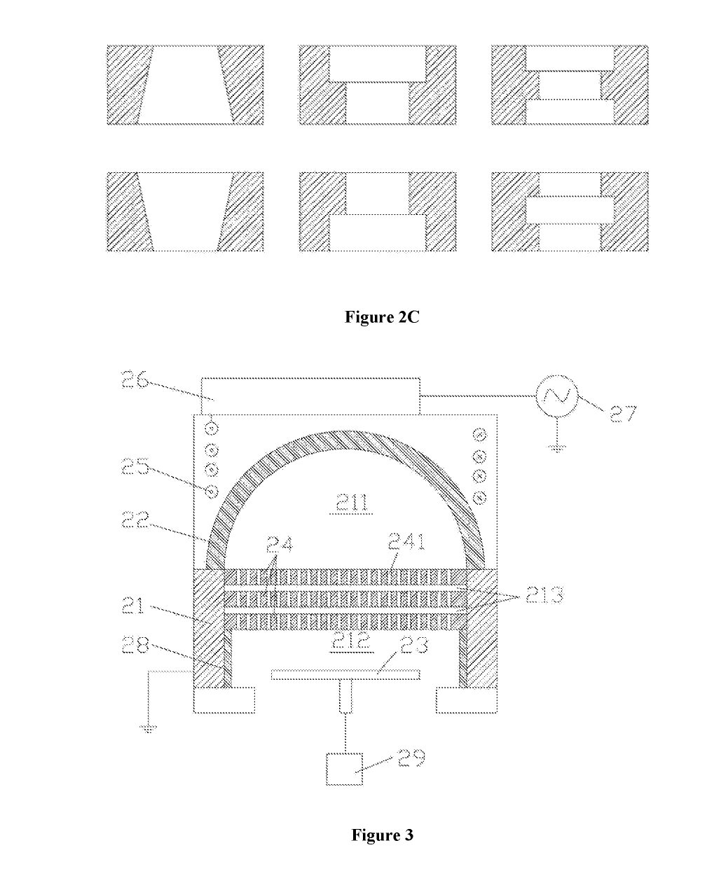

FIG. 2A illustrates the schematic diagram of an exemplary pre-cleaning chamber according to the first embodiment of the present disclosure. As shown in FIG. 2A, the pre-cleaning chamber provided in the present disclosure includes a cavity 21, a top cover 22, a carrying unit 23, an inductance coil 25, an RF matching device 26, and an RF power supply 27. The top cover 22 may have a dome shape and may be positioned at the top of the cavity 21. The top cover 22 may be made of insulating materials, such as ceramic and/or quartz. The carrying unit 23 may be located at the bottom of the cavity 21 to support or load wafers. The inductance coil 25 may be wound and overlying above the top cover 22. The inductance coil 25 may be configured to follow the contour of the outer periphery of the top cover 22. The inductance coil 25 may be connected to the RF power supply 27 through the RF matching unit 26. The RF power supply 27 may be configured to provide RF power to the inductance coil 25 and to form plasma by exciting the reactant gas in the cavity 21. The RF power supply 27 may provide RF power with different frequencies, such as about 400 kHz, 2 MHz, 13.56 MHz, 40 MHz, 60 MHz, and 100 MHz, etc.

An ion filtering unit may be located above the carrying unit 23 in the cavity 21. The ion filter unit may be configured to filter the ions when the plasma is moving downward to the carrying unit 23 from above the carrying unit 23. The structure and function of the ion filtering unit is described in details as follows. In particular, in one embodiment, the ion filtering unit includes a filtering plate 24. The filtering plate 24 may be made of insulating materials or metals coated with insulating materials. The insulating material may be ceramic and/or quartz. The thickness of the filtering plate 24 may range from about 2 mm to about 50 mm. Further, the filtering plate 24 may divide the cavity into an upper sub-cavity 211 and a lower sub-cavity 212. The carrying unit 23 may be located in the lower sub-cavity 212. Optionally, the vertical distance between the filtering plates 24 and the carrying unit 23 may be greater than 20 mm.

A plurality of venting holes 241 may be distributed in the filtering plate 24 to connect the upper sub-cavity 211 and the lower sub-cavity 212. The venting holes 241 may be uniformly distributed across the surface of the filtering plate 24. As shown in FIG. 2B, in some embodiments, the local distribution density of the venting holes 241 may be adjusted based on processing deviations or processing variations in different regions of the wafer surface. Thus, the plasma density corresponding to different regions on the wafer surface may be changed or adjusted. The processing may have improved uniformity. Further, the overall distribution density of the venting holes 241 may be determined or adjusted according to the processing rate. That is, when a higher processing rate is required, the distribution density of the venting holes 241 may be increased accordingly to allow the plasma to pass through the venting holes 241 at a higher rate. When a slower processing rate is required, the distribution density of the venting holes 241 may be decreased accordingly.

In one embodiment, the venting hole 241 may be through holes. The diameter of a venting hole 241 may be no longer than twice the sheath thickness of the plasma. Optionally, the diameter of a through hole may range from about 0.2 mm to about 20 mm. The sheath of plasma is a non-neutral region formed between the boundary of the plasma and the sidewall of the cavity 21. In a pre-cleaning process, the RF power supply 27 may provide RF power to the inductance coil 25 to form plasma in the upper sub-cavity 211. The formed plasma may diffuse towards the carrying unit 23. When the plasma is passing through the venting holes 241 in the filtering plate 24, because the maximum diameter of a venting hole 241 is no longer than twice the sheath thickness of the plasma, the ions in the plasma may transform into other forms, such as atoms, because of the sizes of the venting holes 241. Thus, no ions would be contained in the plasma after passing through the venting holes 241. The plasma may only include free radicals, atoms, molecules, etc. The free radicals, atoms, and molecules may keep diffusing downward until reaching the wafer surface on the carrying unit 23. The plasma may start etching the wafer after reaching the wafer surface. Thus, by using the filtering plate 24, ions in the plasma may be filtered out. Such a process may reduce or prevent adverse effects caused by ions in the plasma on the low-k materials, which are used as dielectrics in the wafers. Product performance may thus be improved.

Because the plasma that has passed through the ion filtering unit does not contain ions, the free radicals, atoms, and molecules may diffuse onto the wafer surface. No bias voltage is needed to be applied on the wafer. Biasing devices such as biasing power supply and matching devices are therefore not needed. The fabrication cost of the pre-cleaning chamber may be further reduced.

In one embodiment, the cavity 21 may include an inner liner 28 positioned on the inner sidewall of the cavity 21. The inner liner 28 may be made of insulating materials, or metals coated with insulating materials. The insulating materials may include ceramic and/or quartz. By using the inner liner 28, the sidewall of the cavity 21 may be protected from being etched or eroded by the plasma. The service time and the maintainability of the pre-cleaning chamber may be improved. The activity of the free radicals in the plasma may be modulated or adjusted. In some embodiments, a protection layer made of insulating materials may be formed on the inner surface of the cavity 21. For instance, an oxidation treatment may be applied on the inner surface, e.g., sidewall, of the cavity 21.

In one embodiment, the carrying unit 23 may include an electrostatic chuck, configured to fix or hold the wafer using electrostatic force. The electrostatic chuck may include a heating device 29 in the electrostatic chunk, configured to heat the wafer. By using the heating device, the activity of the reactions between the plasma and the wafer surface may be increased. Processing rate may be improved or increased. Optionally, the heating temperature of the heating device 29 may range between about 100° C. to about 500° C. The heating period may range between about 5 seconds to about 60 seconds. In some embodiments, the carrying unit 23 may be a wafer holder for holding the wafer. In this case, the wafer holder may include the heating device 29 therein. The heating device 29 may include any suitable heating mechanism such as resistance wire heating.

It should be noted that, in one embodiment, the venting holes 241 may be through holes. In some embodiments, the cross-sections of the venting holes 241 may have various shapes. The specific shapes of the venting holes 241 should not be limited by the embodiments. FIG. 2C illustrates the cross-sectional views of different exemplary venting holes. For example, the cross-section of a venting hole 241 may have a trapezoid shape (i.e., the venting hole are cone shaped), and the diameter of the venting hole 241 may gradually increase or decrease from top to bottom. The cross-section of a venting hole 241 may also be a stepped shape (e.g., the venting hole 241 may consist of two or three cylinders of different diameters). The cross-section of a venting hole 241 along the axis direction may have any suitable shapes such as a greater diameter on one side and a smaller diameter on the other side, a greater diameter on both sides and a smaller diameter in the middle, or a smaller diameter on both sides and a greater diameter in the middle. Optionally, the maximum diameters of a cone-shaped venting hole or a stepped-shaped venting hole may be no longer than 20 mm. The minimum diameter of a cone-shaped venting hole or a stepped-shaped venting hole may be no shorter than 0.2 mm. The cross-section of a venting hole 241 may also have other suitable shapes. It is only required that the venting holes 241 are able to filter out the ions in the plasma.

It should also be note that, in one embodiment, the ion filtering unit may include a filtering plate 24. In embodiments of the present disclosure, the number of filtering plate 24 should not be limited to the embodiment of the present disclosure. As shown in FIG. 3, the ion filtering unit may include N filtering plates 24 arranged vertically in the pre-cleaning chamber, where N is an integer greater than 1. Each filtering plate 24 may be separated from adjacent filtering plates 24 by a certain distance. The filtering plates may divide the cavity into a plurality of sub-cavities. For example, the sub-cavities may be arranged from top to bottom as an upper sub-cavity 211, (N−1) middle sub-cavities 213, and a lower sub-cavity 212. Optionally, the vertical distance between the bottom filtering plates 24, i.e., the filtering plate 24 closest to the carrying unit 23, and the carrying unit 23 may be greater than 20 mm. The vertical distance between two filtering plates 24 should be sufficient long or short so that the arrangement of the filtering plates 24 does not cause sparks, which may be produced by the difference of the floating potential between two filtering plates 24. Further, each filtering plate 24 may include a plurality of venting holes 241 therein to connect the adjacent sub-cavities above and below the filtering plate 24. Further, among all the filtering plates 24, at least one of the filtering plates 24 may include venting holes 241 with maximum diameters no greater than twice the sheath thickness of the plasma. When a plurality of filtering plates 24 are utilized, the thickness of each filtering plate 24 may be reduced accordingly under the premise that the ions in the plasma can be filtered out. For illustrative purposes, only three filtering plates 24 are shown in FIG. 3. In some embodiments, the number of filtering plates 24 may be determined or adjusted according to different applications or designs and should not be limited by the embodiments of the present disclosure.

In some embodiments, as shown in FIG. 3, two adjacent filtering plates 24 may have vertically aligned venting holes 241. In some embodiments, two adjacent filtering plates 24 may have venting holes 241 that are not vertically aligned. The alignment of the venting holes 241 may be adjusted to meet various requirements, such as the processing rate. For example, when a higher processing rate is required, the venting holes 241 may be aligned accordingly to allow the plasma to pass through the venting holes 241 at a higher rate.

It should be further noted that, in practice, the filtering plates 24 may be fixed in the cavity through various mechanisms. For example, flanges may be arranged at locations corresponding to the filtering plates 24 on the inner sidewall of the cavity. The peripheral region on the lower surface of a filtering plate 24 may be fixed and/or jointed onto the upper surface of the corresponding flanges through lap joint connections and/or thread connections.

It should be further noted that, in some embodiments, the number of turns of an inductance coil 25 may be one or more. The number of turns of an inductance coil 25 may be determined or adjusted according to the plasma distribution in the upper sub-cavity 211. In addition, the diameters of the turns of the helical solenoid may be same, or may increase, from the top to the bottom of the helical solenoid.

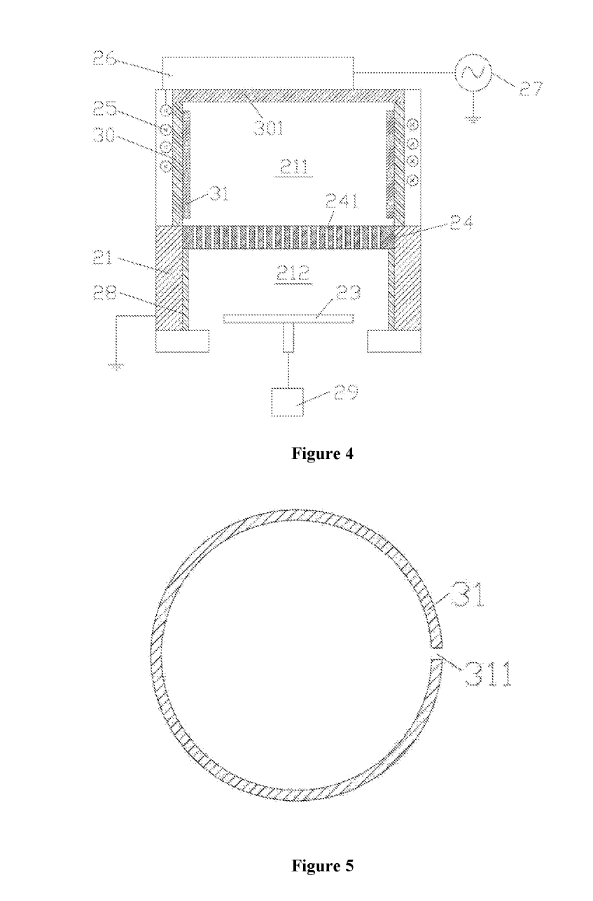

FIG. 4 illustrates the schematic diagram of an exemplary pre-cleaning chamber according to the second embodiment of the present disclosure. As shown in FIG. 4, compared to the pre-cleaning chamber disclosed in the first embodiment, the structure of the top cover of the pre-cleaning chamber disclosed in the second embodiment is different. Structures and functions of other parts in the pre-cleaning chamber disclosed in the second embodiment may be the same as the first embodiment.

The top cover of the pre-cleaning chamber is described in detail. In particular, the top cover 30 may have a barrel shape with a ceiling 301. The top cover 30 may be made of insulating materials, such as ceramic and/or quartz. The barrel-shaped structure refers to a cylinder with a closed periphery formed by surrounding of the side wall of the top cover 30, which is closed by the ceiling 301 at the top, that is, the top cover 30 is similar to an inverted bucket. Compared to a dome shaped top cover, a top cover 30 with the barrel shape may be easier to manufacture. The fabrication cost to make the top cover 30 can be reduced. The fabrication cost and the utilization cost of the pre-cleaning chamber can thus be reduced. The inductance coil 25 may be wound and overlying along an outer periphery of a sidewall of the top cover 30. The inductance coil 25 may be a helical solenoid with one or more turns.

Further, a Faraday shielding piece 31 may be arranged on the inner sidewall of the barrel-shaped top cover 30. The Faraday shielding piece 31 may be made of metals or insulating materials coated with suitable conductive materials. The insulating materials may include ceramic and/or quartz. By using the Faraday shielding piece 31, electromagnetic field can be shielded to reduce plasma erosion on the upper sub-cavity 211. The service time of the upper sub-cavity 211 may be increased or improved. The cavity may be easier to clean and the utilization cost of the cavity may be reduced. It should be noted that, to ensure the Faraday shielding piece 31 maintains at the floating potential, the top of the Faraday shield piece 31 should be lower than the upper boundary of the sidewall of the top cover 30. In addition, the top of the Faraday shield piece 31 should not contact the ceiling 301, and the bottom of the shield piece 31 should not contact the cavity 21.

Optionally, the Faraday shielding piece 31 may include at least one slit 311 along the axial direction and extending through the Faraday shielding piece 31. As shown in FIG. 5, at the slit 311, the Faraday shielding piece 31 may be completely disconnected. That is, the Faraday shielding piece 31 may not have a continuous barrel shape. The slit 311 may be configured to effectively prevent eddy-current losses and heating issues of the Faraday shield 31.

Another aspect of the present disclosure includes a semiconductor processing apparatus. The semiconductor processing apparatus may include one or more of the disclosed pre-cleaning chambers.

In the embodiment of the semiconductor processing apparatus provided in the present disclosure, using the pre-cleaning chamber provided in the present disclosure, the performance of related products may be improved by preventing the adverse effects on the low-k materials caused by ions in plasma.

What claimed is:

1. A pre-cleaning chamber, comprising:
a cavity;
a top cover of the cavity;
an ion filtering unit with venting holes, the ion filtering unit being configured to divide the cavity into an upper sub-cavity and a lower sub-cavity and to filter out ions from plasma when the plasma is moving through the filtering unit from the upper sub-cavity to the lower sub-cavity; and
a carrying unit located in the lower sub-cavity for supporting a wafer.

2. The pre-cleaning chamber according to claim 1, wherein:
the ion filtering unit includes one or more filtering plates; and
each filtering plate includes a plurality of venting holes distributed in the filtering plate, and at least one of the filtering plates includes venting holes with maximum diameters no greater than a sheath thickness of plasma times two.

3. The pre-cleaning chamber according to claim 2, wherein the ion filtering unit includes one filtering plate, the one filtering plate dividing the cavity into the upper sub-cavity and the lower sub-cavity, the plurality of venting holes connecting the upper sub-cavity and the lower sub-cavity.

4. The pre-cleaning chamber according to claim 2, wherein the ion filtering unit includes N filtering plates arranged vertically in the cavity, N being an integer greater than 1; and the filtering plates dividing the cavity into the lower sub-cavity, (N−1) middle sub-cavities, and the upper sub-cavity.

5. The pre-cleaning chamber according to claim 2, wherein venting holes are distributed uniformly in the filtering plate.

6. The pre-cleaning chamber according to claim 2, wherein venting holes are distributed in the filtering plate according to processing deviations on a wafer placed on the carrying unit.

7. The pre-cleaning chamber according to claim 2, wherein a distribution density of the venting holes is determined according to a processing rate.

8. The pre-cleaning chamber according to claim 2, wherein a venting hole is a through hole with a trapezoid shaped cross section or a step-shaped cross section.

9. The pre-cleaning chamber according to claim 2, wherein the venting holes are through holes, a diameter of a venting hole ranging from about 0.2 mm to about 20 mm.

10. The pre-cleaning chamber according to claim 2, wherein the venting holes are cone-shaped holes or multi-cylinder-shaped holes, a maximum diameter of a venting hole being no greater than 20 mm, and a minimum diameter of a venting hole being no smaller than 0.2 mm.

11. The pre-cleaning chamber according to claim 2, wherein the filtering plate is made of an insulating material, a metal coated with insulating materials, or a combination thereof.

12. The pre-cleaning chamber according to claim 2, wherein a thickness of a filtering plate ranges from about 2 mm to about 50 mm.

13. The pre-cleaning chamber according to claim 1, wherein the carrying unit includes a heating device for heating the wafer.

14. The pre-cleaning chamber according to claim 13, wherein the carrying unit includes an electrostatic chuck for fixing the wafer by electrostatic forces, and the heating device is positioned in the electrostatic chuck.

15. The pre-cleaning chamber according to claim 1, wherein the cavity includes a protection layer on an inner surface of the cavity, the protection layer being of an insulating material.

16. The pre-cleaning chamber according to claim 1, wherein the cavity further includes an inner liner on an inner sidewall of the cavity, the inner liner being made of an insulating material, a metal coated with insulating material, or a combination thereof.

17. The pre-cleaning chamber according to claim 1, wherein the top cover is of a dome shape, and is made of an insulating material.

18. The pre-cleaning chamber according to claim 1, wherein the top cover is of a barrel shape, with a top ceiling, and made of an insulating material.

19. The pre-cleaning chamber according to claim 18, wherein the top cover further includes a Faraday shielding piece positioned on an inner sidewall of the top cover, the Faraday shielding piece being made of a metal, an insulating material coated with a conductive material, or a combination thereof.

20. The pre-cleaning chamber according to claim 19, wherein the Faraday shielding piece includes a least one slit along an axial direction of and extending through the shielding piece.

21. The pre-cleaning chamber according to claim 1, further including an inductance coil, and an RF matching device and a radio frequency (RF) power supply connected to the inductance coil sequentially, wherein:
the inductance coil is wound and overlying along an outer periphery of a sidewall of the top cover, the inductance coil being a helical solenoid with one or more turns; and
the RF power supply provides RF power to the inductance coil.

22. The pre-cleaning chamber according to claim 21, wherein diameters of turns of the helical solenoid are same or increase from top to bottom of the helical solenoid.

23. A plasma processing apparatus, comprising one or more of the pre-cleaning chambers according to claim 1.

24. A wafer pre-cleaning process, comprising:
providing a pre-cleaning chamber including:
a cavity;
a top cover of the cavity, and
an ion filtering unit dividing the cavity into an upper sub-cavity and a lower sub-cavity, the ion filtering unit including venting holes; and
a carrying unit located in the lower sub-cavity;
placing a wafer on the carrying unit;
forming plasma in the upper sub-cavity;
filtering out ions from the plasma when the plasma moves through the filtering unit from the upper sub-cavity into the lower sub-cavity through the venting holes; and
pre-cleaning the wafer on the carrying unit.

25. The process according to claim 24, wherein the ion filtering unit includes one or more filtering plates, each filtering plate having a plurality of venting holes.

26. The process according to claim 24, wherein the top cover is of a dome shape or of a barrel shape.
